(19) United States
(12) Patent Application Publication
(10) Pub. No.: US 2009/0160490 A1
(43) Pub. Date: Jun. 25, 2009

(54) REFERENCE VOLTAGE GENERATOR OF ANALOG-TO-DIGITAL CONVERTER

(75) Inventors: Michael CHOI, Seoul (KR); Jung-ho LEE, Gunpo-si (KR); Jung-eun LEE, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co., Ltd., Suwon-si (KR)

(21) Appl. No.: 12/137,672

(22) Filed: Jun. 12, 2008

(30) Foreign Application Priority Data
Dec. 24, 2007 (KR) 10-2007-0136074

(51) Int. Cl. H03K 5/153

(52) U.S. Cl. 327/51; 327/74

(57) ABSTRACT

A reference voltage generator, which is used in an analog-to-digital converter, minimizes influence of kickback noise by dividing a full scale reference voltage into a number of reference voltages using a ladder resistor unit, and applying the number of reference voltages to a number of comparators, and matches a reference common mode voltage to an input common mode voltage by forming a common feedback loop using another ladder resistor unit which is a replica of the ladder resistor unit. Therefore, since kickback noise is locally discharged by a decoupling capacitor connected to each ladder resistor and a peak value of the kickback noise is also reduced, it is possible to optimize the ladder resistor unit according to power consumption. Also, since the common feedback loop is formed as a replica of the ladder resistor unit, it is possible to match a reference common mode signal to an input common mode signal.

### CROSS REFERENCE TO RELATED APPLICATIONS

This application claims priority from Korean Patent Application No. 10-2007-0136074, filed on Dec. 24, 2007, the disclosure of which is incorporated herein in its entirety by reference.

### BACKGROUND OF THE INVENTION

1. Field of the Invention

The present invention relates to a reference voltage generator of an analog-to-digital converter, and more particularly, to a reference voltage generator of an analog-to-digital converter, which can optimize power consumption of a system by minimizing influence of kickback noise.

2. Description of the Related Art

An analog-to-digital converter compares an analog signal with a discrete reference voltage, and converts the analog signal into a digital signal. An important factor for determining resolution of an analog-to-digital converter is the number of reference voltages that are to be compared with an input analog signal.

A reference voltage generator used in an analog-to-digital converter includes a reference ladder consisting of a plurality of resistors, and a unity-gain feedback buffer which is a voltage source connected to both ends of the reference ladder.

The reference voltage generator has two main functions: a function of dividing a voltage into a plurality of voltages and applying the plurality of voltages respectively to comparators constructing the analog-to-digital converter to provide reference voltages that are to be compared with an input voltage, and a function of matching a reference common mode voltage to an input common mode voltage.

Each comparator of the analog-to-digital converter compares an analog waveform with a reference voltage in synchronization with a predetermined clock signal, and generates a digital code using a zero crossing technique. At this time, kickback noise may be generated by the clock signal and flow into the reference voltage generator.

Such kickback noise is induced by the clock signal in the comparator, or generated when an analog signal causes capacitive coupling with a certain device of the comparator. The kickback noise influences the reference ladder of the reference voltage generator and deteriorates performance of the system. The reference voltage that is to be compared with the analog signal has to be kept constant. However, if such kickback noise is generated, errors in zero-crossing are caused.

In order to reduce kickback noise, a method of reducing a settling time of kickback noise by constructing a reference ladder with resistors with small resistance has been developed, however, the method is not suitable for a high-speed analog-to-digital converter, and also power consumption is increased by voltage buffers at both ends of the reference ladder which is a discharge path of kickback noise.

### SUMMARY OF THE INVENTION

The present invention provides a reference voltage generator for minimizing influence of kickback noise and optimizing power consumption, thereby stably providing a reference voltage to an analog-to-digital converter.

According to an aspect of the present invention, there is provided a reference voltage generator of an analog-to-digital converter, including: a main ladder resistor unit including a plurality of resistors connected in series to each other, dividing a full scale reference voltage into a plurality of reference voltages and distributing the plurality of reference voltages to a plurality of comparators via a plurality of reference nodes, wherein the plurality of reference nodes are located respectively between the plurality of resistors; a capacitor unit including a plurality of capacitors connected respectively to the plurality of reference nodes of the main ladder resistor unit, locally distributing discharge paths of kickback noise, and reducing a peak value of the kickback noise; a sub ladder resistor unit having the same configuration as the main ladder resistor unit, and connected in parallel to the main ladder resistor unit; and a feedback loop unit connected to the sub ladder resistor unit and matching a reference common mode voltage to an input common mode voltage.

The capacitor unit may include a plurality of bypass capacitors or a plurality of decoupling capacitors connected respectively to the plurality of reference nodes of the main ladder resistor unit.

The sub ladder resistor unit and the main ladder resistor unit may be connected in parallel via MOS transistors, the MOS transistors connected to both ends of each of the sub ladder resistor unit and the main ladder resistor unit.

The feedback loop unit may include: an amplifier receiving the input common mode voltage; and a negative feedback circuit connected from a node of the sub ladder resistor unit to a non-inverting terminal of the amplifier.

An output terminal of the amplifier may be connected to a gate of a PMOS transistor, and one end of the sub ladder resistor unit may be connected to a drain of a PMOS transistor.

The full scale reference voltage of the main ladder resistor unit is adjusted by a current flowing through the main ladder resistor unit. The current flowing through the main ladder resistor unit may be supplied from a predetermined current source via a current mirror.

Each reference node may be a connection point between two neighboring resistors of the plurality of resistors constructing the main ladder resistor unit, or one end of a resistor of the plurality of resistors. A value of the current flowing through the main ladder resistor unit may be equal to a value of a current flowing through the sub ladder resistor unit.

The full scale reference voltage may be defined by a product of a value of the current flowing through the main ladder resistor unit and a sum of resistance values of the plurality of resistors constructing the main ladder resistor unit, and the full scale reference voltage applied to the main ladder resistor unit is applied to the sub ladder resistor unit.

The reference voltage generator may further include: a current source which provides a reference current; and a current mirror which receives the reference current from the current source, and transfers the reference current to the main ladder resistor unit and the sub ladder resistor unit.

Additional aspects of the invention will be set forth in the description which follows, and in part will be apparent from the description, or may be learned by practice of the invention.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain aspects of the invention.

FIG. 1 shows a reference voltage generator used for a flash type analog-to-digital converter, according to an exemplary embodiment of the present invention; and

FIG. 2 is a circuit diagram of the reference voltage generator illustrated in FIG. 1, according to an exemplary embodiment of the present invention.

### DETAILED DESCRIPTION OF EXEMPLARY EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

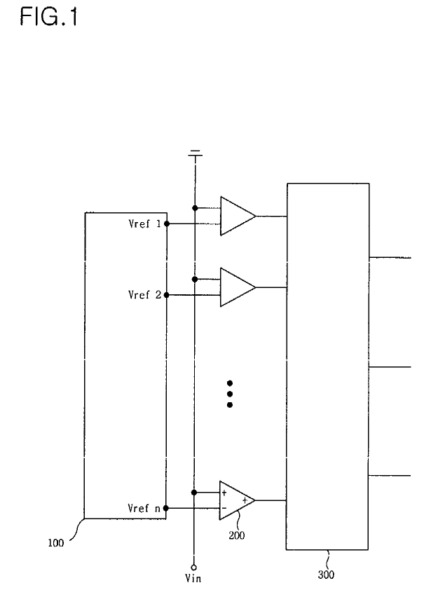

FIG. 1 shows a reference voltage generator 100 used in an analog-to-digital converter (hereinafter, referred to as an ADC), according to an embodiment of the present invention.

In FIG. 1, a flash type ADC in which a plurality of comparators (200 for each) are connected in parallel to each other is used. Each comparator 200 compares an analog input signal with a reference signal provided from the reference voltage generator 100, and generates a discrete code. For example, the comparator 200 compares an input analog voltage Vin with a reference voltage Vref1 provided from the reference voltage generator 100, and outputs a value “1” if the input analog voltage Vin is higher than the reference voltage Vref1, and outputs a value “0” if the input analog voltage Vin is lower than the reference voltage Vref1. The discrete code (for example, the value “1” or “0”) is input to a digital encoder 300, and encoded to a digital signal by the digital encoder 300.

The comparator 200 can include a track/hold switch for holding the input analog voltage Vin, and a preamplifier for comparing the input analog voltage Vin with the reference voltage Vref1 and amplifying the result of the comparison according to zero-crossing information.

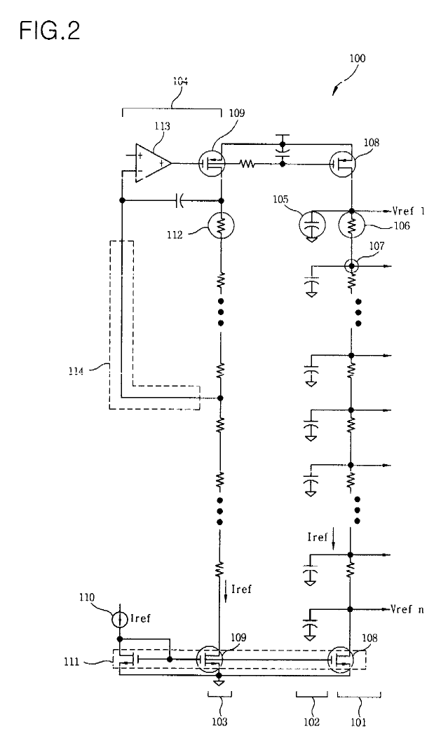

FIG. 2 is a circuit diagram of the reference voltage generator 100 illustrated in FIG. 1, according to an embodiment of the present invention.

Referring to FIG. 2, the reference voltage generator 100 includes a main ladder resistor unit 101, a capacitor unit 102, a sub ladder resistor unit 103, and a feedback loop unit 104. The reference voltage generator 100 can further include a current source 110 and a current mirror 111.

The main ladder resistor unit 101 divides a full scale reference voltage into a plurality of reference voltages Vref1 through Vrefn, and distributes the plurality of reference voltages Vref1 through Vrefn at respective reference nodes respectively to comparators 200 (see FIG. 1). For this operation, the main ladder resistor unit 101 can include a plurality of resistors 106 (106 for each) which are connected in series to each other.

In this specification, the full scale reference voltage means a voltage applied to the main ladder resistor unit 101, and the reference voltages Vref1 through Vrefn mean voltages at the respective reference nodes, which are to be compared with an input voltage by the comparators 200. Also, each reference node means a connection point between the resistors 106 constructing the main ladder resistor unit 101, or an end of each resistor 106, and is a contact (for example, denoted by a reference number 107) to be connected to the corresponding comparator 200.

Since the respective resistors 106 of the main ladder resistor 101 are connected in series to each other, the full scale reference voltage is divided into the plurality of reference voltages Vref1 through Vrefn according to the voltage distribution law. For example, when the reference voltage generator 100 is used in an n-bit flash ADC, 2ⁿ resistors having the same resistance are connected in series to each other, and the full scale reference voltage is uniformly divided into a plurality of reference voltages Vref1 through Vrefn which are applied to the comparators 200.

The full scale reference voltage can be adjusted by a current flowing through the main ladder resistor unit 101. In order to adjust the full scale reference voltage, the current source 110 may generate a reference current Iref, and the current mirror 111 may provide the reference current Iref to the main ladder resistor unit 101. The full scale reference voltage can be defined by a product of the value of the current flowing through the main ladder resistor unit 101 and a sum (N×Rtap) of the resistance values of the resistors of the main ladder resistor unit 101.

Also, the current source 110 may be a dependent current source which depends on the resistance value of the main ladder resistor unit 101 so that the full scale reference voltage is kept constant by changing the current passing through the main ladder resistor unit 101 when the resistance value of the main ladder resistor unit 101 changes.

Each capacitor unit 102 is connected to each reference node of the main ladder resistor unit 101, and performs a function of locally distributing discharge paths of kickback noise and suppressing a peak value of the kickback noise. For this function, the capacitor unit 102 can include a bypass capacitor or a decoupling capacitor 105 which is connected to each reference node of the main ladder resistor unit 101.

If the kickback noise, which is a noise component induced by a clock signal from the comparators 200 following the main ladder resistor unit 101, flows into the main ladder resistor unit 101, the kickback noise deteriorates performance of the system. Also, kickback noise may be generated when an analog signal input to the comparators 200 causes capacitive coupling with any device in the comparators 200.

If such kickback noise flows into the reference nodes 107 of the main ladder resistor unit 101 from the comparator 200, the capacitor unit 102 discharges the kickback noise to the decoupling capacitor 105, thereby quickly removing the kickback noise. Since a device (that is, the bypass capacitor or the decoupling capacitor 105) having a capacitance component is connected to each reference node of the main ladder resistor unit 101, the size of the kickback noise can also be reduced.

The sub ladder resistor unit 103 has the same configuration as that of the main ladder resistor unit 101, and is connected in parallel to the main ladder resistor 101. The parallel connection means connects the sub ladder resistor unit 103 to the main ladder resistor unit 101 in parallel so that the same voltage can be applied to the sub ladder resistor unit 103 and the main ladder resistor unit 101. For example, the sub ladder resistor unit 103 and the main ladder resistor unit 101 can be connected to each other via first and second MOS transistors 108 and 109 having a common gate terminal.

Also, since the sub ladder resistor unit 103 has the same configuration as the main ladder resistor unit 101, as described above, the resistors 112 of the sub ladder resistor unit 103 are the same in the number, locations, resistance values, etc., as the resistors 106 of the main ladder resistor unit 101. That is, the sub ladder resistor unit 103 is a replica of the main ladder resistor 101, except that the main ladder resistor unit 101 is connected to the capacitor unit 102. Also, a current flowing through the sub ladder resistor unit 103 has the same value as the current flowing through the main ladder resistor unit 101. Accordingly, the voltage applied to the sub ladder resistor unit 103 can also be set to the full scale reference voltage of the main ladder resistor unit 101.

The feedback loop unit 104 performs a function of matching a reference common node voltage to an input common mode voltage. In order to perform the function, the feedback loop unit 104 can include an amplifier 113 which receives an input common mode voltage and whose output terminal is connected to the sub ladder resistor unit 103, and a negative feedback circuit 114 which is connected from a node of the sub ladder resistor unit 103 to a non-inverting terminal of the amplifier 1 13.

Here, the node of the sub ladder resistor unit 103 from which the negative feedback circuit 114 diverges is, like the reference node 107, a connection point between the resistors 112 constructing the sub ladder resistor unit 103.

For example, the feedback loop unit 104 is configured in such a manner that the output terminal of the amplifier 113 is connected to the gate of the PMOS transistor 109, one end of the sub ladder resistor unit 103 is connected to the drain of the PMOS transistor 109, and a node of the sub ladder resistor unit 103 is connected to the non-inverting terminal of the amplifier 113.

The reference current Iref supplied from the current source 110 is provided to the sub ladder resistor unit 103 and the main ladder resistor unit 101 via the current mirror 111. Here, since the full scale reference voltage ΔV is defined as the product of the reference current Iref and the sum (N*Rtap) of resistance values of the resistors 112, only the range of the full scale reference voltage ΔV is determined. Accordingly, a reference common mode voltage of the full scale reference voltage ΔV needs to be matched to a common mode voltage of an input common mode voltage Vin.

Since a voltage which is equal to the full scale reference voltage of the main ladder resistor unit 101 is applied to the sub ladder resistor unit 103, a common mode feedback loop is formed in the sub ladder resistor unit 103 in order to match the common mode voltage of the full scale reference voltage ΔV to the common mode voltage of the input common mode voltage Vin.

Since an input common mode voltage Vin is applied to the amplifier 113, the negative feedback circuit 114 is started at the center part (that is, a location where the reference common mode voltage is formed) of the sub ladder resistor unit 103, however, the present invention is not limited to this. If any other voltage is applied to the amplifier 113, the negative feedback circuit 114 can be started at any other part in the sub ladder resistor unit 103. In general, since decoupling capacitors (for example, 105) can destabilize a feedback loop, the feedback loop unit 104 is formed in the sub ladder resistor unit 103 not having any decoupling capacitor.

The operation of the reference voltage generator 100 according to the current embodiment of the present invention will be described below. First, the reference current Iref flows to the sub ladder resistor unit 103 and the main ladder resistor unit 101 via the current source 110 and the current mirror 111. Due to the reference current Iref, a full scale reference voltage (ΔV=Iref*N*Rtap) is applied to the main ladder resistor unit 101.

After only the range of the full scale reference voltage ΔV is determined, a common mode voltage of the full scale reference voltage ΔV is matched to an input common mode voltage. Since the sub ladder resistor unit 103 has the same configuration as the main ladder resistor unit 101, the same voltage as the full scale reference voltage ΔV of the main ladder resistor unit 101 is also applied to the sub ladder resistor unit 103. Accordingly, the feedback loop unit 104 can match the reference common mode voltage to the input common mode voltage, through a common feedback loop, along with the sub ladder resistor unit 103.

Thus, the main ladder resistor unit 101 divides the resultant full scale reference voltage into a plurality of reference voltages and applies the reference voltages respectively to the comparators 200, while the reference common mode voltage is matched to the input common mode voltage. At this time, kickback noise may flow back from the comparators 200 to the main ladder unit 101, due to a clock signal or input coupling. In this case, the capacitor unit 102 discharges the kickback noise locally, thereby quickly removing the kickback noise.

As a result, in the reference voltage generator 100 of the analog-to-digital converter, according to the current embodiment of the present invention, since the capacitor unit 102 connected to the reference nodes of the main ladder resistor unit 101 minimizes influence of kickback noise, the resistors 106 of the main ladder resistor unit 101 can be optimized according to power consumption. Also, when a full scale reference voltage of the main ladder resistor unit 101 is adjusted depending on a current, the full scale reference voltage can be easily adjusted by the sub ladder resistor unit 103 and the feedback loop unit 104.

It will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

What is claimed is:

1. A reference voltage generator of an analog-to-digital converter, comprising:
a main ladder resistor unit including a plurality of resistors connected in series to each other, dividing a full scale reference voltage into a plurality of reference voltages and distributing the plurality of reference voltages to a plurality of comparators via a plurality of reference nodes, wherein the plurality of reference nodes are located respectively between the plurality of resistors;
a capacitor unit which includes a plurality of capacitors connected respectively to the plurality of reference nodes of the main ladder resistor unit, locally distributes discharge paths of kickback noise, and reduces a peak value of the kickback noise;
a sub ladder resistor unit having the same configuration as the main ladder resistor unit, and connected in parallel to the main ladder resistor unit; and
a feedback loop unit connected to the sub ladder resistor unit and matching a reference common mode voltage to an input common mode voltage.

2. The reference voltage generator of claim 1, wherein the capacitor unit comprises a plurality of bypass capacitors or a plurality of decoupling capacitors connected respectively to the plurality of reference nodes of the main ladder resistor unit.

3. The reference voltage generator of claim 1, wherein the sub ladder resistor unit and the main ladder resistor unit are connected in parallel via MOS transistors, the MOS transistors connected to both ends of each of the sub ladder resistor unit and the main ladder resistor unit.

4. The reference voltage generator of claim 1, wherein the feedback loop unit comprises:
an amplifier which receives the input common mode voltage; and
a negative feedback circuit connected from a node of the sub ladder resistor unit to a non-inverting terminal of the amplifier.

5. The reference voltage generator of claim 4, wherein an output terminal of the amplifier is connected to a gate of a PMOS transistor, and one end of the sub ladder resistor unit is connected to a drain of a PMOS transistor.

6. The reference voltage generator of claim 1, wherein the full scale reference voltage of the main ladder resistor unit is adjusted by a current flowing through the main ladder resistor unit.

7. The reference voltage generator of claim 6, wherein the current flowing through the main ladder resistor unit is supplied from a predetermined current source via a current mirror.

8. The reference voltage generator of claim 1, wherein each reference node is a connection point between two neighboring resistors of the plurality of resistors constructing the main ladder resistor unit, or one end of a resistor of the plurality of resistors.

9. The reference voltage generator of claim 1, wherein a value of the current flowing through the main ladder resistor unit is equal to a value of a current flowing through the sub ladder resistor unit.

10. The reference voltage generator of claim 1, wherein the full scale reference voltage is defined by a product of a value of the current flowing through the main ladder resistor unit and a sum of resistance values of the plurality of resistors constructing the main ladder resistor unit, and the full scale reference voltage applied to the main ladder resistor unit is applied to the sub ladder resistor unit.

11. The reference voltage generator of claim 1, further comprising:
a current source which provides a reference current; and
a current mirror which receives the reference current from the current source, and transfers the reference current to the main ladder resistor unit and the sub ladder resistor unit.
